(19) United States
(12) Patent Application Publication
(10) Pub. No.: US 2024/0273249 A1
(43) Pub. Date: Aug. 15, 2024

(54) METHOD FOR CREATING A KITCHEN

(71) Applicant: BULTHAUP GMBH & CO. KG, Aich, Bodenkirchen (DE)

(72) Inventor: Marc ECKERT, Bodenkirchen (DE)

(21) Appl. No.: 18/020,156

(22) PCT Filed: Sep. 24, 2021
(86) PCT No.: PCT/EP2021/076358

§ 371 Date: Aug. 3, 2023

(30) Foreign Application Priority Data
Sep. 29, 2020 (DE) 10 2020 005 950.3

(51) Int. Cl. G06F 30/13

(52) U.S. Cl. CPC G06F 30/13

(57) ABSTRACT

The invention relates to a method for creating a kitchen, comprising the following steps: arranging at least one virtual main body in three-dimensional space, arranging at least one functional element in the virtual main body, fixing the position of the actual main body based on the arranged functional element.

The present invention relates to a method of creating a kitchen.

It is known from the prior art in the preparation of a kitchen to first manufacture at least one base body, i.e. a carcass, and then to introduce the suitable functional elements such as drawers, etc. into it.

This procedure is associated with the disadvantage that in the manufacture of the carcass, that is typically produced from chipboard, a comparatively large amount of offcuts arise and that plinths may be necessary, etc.

It is the underlying object of the present invention to provide a method by means of which a kitchen can be produced in a comparatively simple and sustainable manner.

This object is achieved by a method having the features of claim 1.

Provision is accordingly made that the method comprises the following steps:
a) arranging at least one virtual base body in three-dimensional space;
b) arranging at least one functional element in the virtual base body; and
c) determining, i.e. defining, the actual base body on the basis of the functional element arranged in accordance with step b).

The arrangement of one or more virtual base bodies in a three-dimensional space that can e.g. be spanned by three x, y, and z coordinates respectively standing perpendicular on one another takes place first.

Said base bodies are placed in a space, with the possible placement positions of the base bodies in the space and/or the base bodies themselves being scalable and/or following a grid dimension.

The base bodies such as a tall unit, a floor unit, a wall unit or wall carcass, e.g. a freestanding cabinet, or a so-called island are initially only virtually fixed in position by a computer system or the like. This fixing is provisional and can be easily changed by the user.

The base bodies or base volumes provisionally fixed in this manner are now filled with one or more functional elements in a further step. This step also takes place by user input by means of a computer system or the like.

The computer based determination of the actually required base body takes place in the third step on the basis of the functional element or elements. The sum of the functional elements such as a plurality of drawers arranged above one another thus defines the actually required base body, e.g. its length, width, depth, etc.

This means that in accordance with the present invention “from top to bottom” or a larger unit (carcass) does not form the starting point and then the smaller units (functional elements) are adapted to them. Provision is made in accordance with the invention that the smaller units, i.e. the functional elements, form the starting point and the matching larger unit, i.e. the carcass, is only then prepared and finally manufactured on the basis thereof.

This has the consequence that the carcass or the base body is adapted to the functional elements required on the part of the customer with an exact fit so that no offcuts are produced and thus a particularly sustainable procedure for the manufacture of a kitchen is provided.

The kitchen is then produced on the basis of the base bodies and functional elements defined in this manner.

The base body is preferably a body comprising a volume such as the carcass of a tall unit, a wall unit, a row of wall units, a freestanding cabinet, etc.

The base body itself can be scalable with respect to its dimensions or can correspond to a specific grid dimension. The same can also apply accordingly to the functional element.

The functional elements can be any desired element that interacts with the base body and is preferably arranged in or at it. The functional element can, for example, be one or more of the elements drawer, heat source, water source, appliance, air inflow or outflow or extractor fan, panel, front, or box.

The fixing of the functional element arranged in accordance with step b) can take place as a further method step. It is to be understood by this that its position in space or in or at the base body is fixed. Before the fixing, the functional element is still displaceable or positionable at a different point in space such as a graphic or a table in a text file.

The fixing of the base body arranged in accordance with step a) can take place as a further step after step c). It is to be understood by this that its position is fixed in space. Provision can be made prior to this fixing that the base body is movable in space either as desired or following a specific grid dimension in space.

It is conceivable that the fixing of the base body and/or of the functional element can be canceled again, optionally by a special command that is input via a computer interface such as by means of a computer mouse, so that a correction is possible.

It is conceivable that at least one blade or a plinth or a closure element such as a door, flap, etc. is used to fix the functional element, with the blade preferably being a pane of metal, in particular of aluminum. If this is positioned, the functional element is fixed.

One or more adapters can be arranged on this blade.

The adapter can be an opening means for opening a functional element such as a hinge or the like.

It is conceivable that the adapter is releasably arranged, e.g. by means of a clip technology, at the blade and/or at the base body. This brings about the advantage that a release of the adapter and thus also a repositioning of the blade can be carried out by customer service.

The actual production of the kitchen can then take place on the basis of the fixing of the base body and of the functional element both with respect to the dimensioning and with respect to the arrangement in space or in the base body.

The present invention further relates to a kitchen that is manufactured in accordance with a method in accordance with one of the claims 1 to 10.

It is pointed out at this point that the terms “a” and “one” do not necessarily refer to exactly one of the elements, even though this represents a possible embodiment, but can also designate a plurality of elements. The use of the plural equally also includes the presence of the element in question in the singular and, conversely, the singular also includes a plurality of the elements in question.

Further details and advantages of the invention will be explained in more detail with reference to an embodiment described in the following.

In a first step, a space or a coordinate system in which the kitchen is to be arranged is provided by means of a computer.

A plurality of virtual base volumes, i.e., base bodies, are then likewise provisionally arranged in the space by means of a computer. “Virtual” is to be understood such that the base body dimensioning and positioning are not yet fixed, but rather stand as placeholders for the ultimately used base body.

The base body or bodies can be displaceable, in the space, for example by means of a computer mouse, with this displacement taking place either such that the base bodies are positionable at any desired points or only in specific grid positions.

Functional elements are then defined such as drawers, fronts, dishwashers, stoves, etc., and indeed with respect to their number and positions in the virtual base body.

Once this definition of the functional elements has taken place, the fixing of the actual base body takes place as a further step on the basis of the previously arranged functional elements. In other words, the sum of the functional elements thus defines the shape and/or dimension of the base body.

Blades that fix the functional elements in their positions are then arranged. They can e.g. be panes, e.g. of aluminum or another metal, wood, etc.

Adapters are arranged at the blades that fix the blades at the base bodies. The blades are arranged releasably from the blade and/or from the base body so that a different arrangement can take place as required.

The kitchen is then actually produced on the basis of these data.

1. A method of creating a kitchen, comprising the following steps:
a) arranging at least one virtual base body in three-dimensional space;
b) arranging at least one functional element in the virtual base body; and
c) defining, the actual base body on the basis of the functional element arranged in accordance with step b).

2. A method in accordance with claim 1, wherein the base body is selected from a tall unit, wall unit, row of wall units, or a freestanding cabinet.

3. A method in accordance with claim 1, wherein the base body is scalable.

4. A method in accordance with claim 1, wherein the functional element is scalable.

5. A method in accordance with claim 1, wherein the functional element is at least one of a drawer, heat source, water source, appliance, air inflow or outflow, panel, front, or box.

6. A method in accordance with claim 1, wherein the fixing of the functional element arranged in accordance with step b) takes place as step b′) between steps b) and c).

7. A method in accordance with claim 6, wherein at least one blade is used to fix the functional element, with the blade preferably being a pane of metal, in particular of aluminum.

8. A method in accordance with claim 7, wherein one or more adapters are arranged at the blade.

9. A method in accordance with claim 8, wherein the adapter constitutes means for opening a functional element.

10. A method device in accordance with claim 8, wherein the adapter is releasably arranged at the blade.

11. A kitchen produced by the method in accordance with claim 1.

12. A method in accordance with claim 2, wherein the base body is scalable.

13. A method in accordance with claim 12, wherein the functional element is scalable.

14. A method in accordance with claim 3, wherein the functional element is scalable.

15. A method in accordance with claim 2, wherein the functional element is scalable.

16. A method in accordance with claim 15, wherein the functional element is at least one of a drawer, heat source, water source, appliance, air inflow or outflow, panel, front, or box.

17. A method in accordance with claim 14, wherein the functional element is at least one of a drawer, heat source, water source, appliance, air inflow or outflow, panel, front, or box.

18. A method in accordance with claim 13, wherein the functional element is at least one of a drawer, heat source, water source, appliance, air inflow or outflow, panel, front, or box.

19. A method in accordance with claim 12, wherein the functional element is at least one of a drawer, heat source, water source, appliance, air inflow or outflow, panel, front, or box.

20. A method in accordance with claim 11, wherein the functional element is at least one of a drawer, heat source, water source, appliance, air inflow or outflow, panel, front, or box.
